(19) United States
(12) Patent Application Publication
(10) Pub. No.: US 2024/0270104 A1
(43) Pub. Date: Aug. 15, 2024

(54) APPARATUS AND METHOD FOR CHARGING ELECTRIC VEHICLES

(71) Applicant: Rodney Alexander Walker, Williamstown, Victoria (AU)

(72) Inventor: Rodney Alexander Walker, Williamstown, Victoria (AU)

(21) Appl. No.: 18/567,170

(22) PCT Filed: Jun. 8, 2021
(86) PCT No.: PCT/AU2021/050571

§ 371 Date: Dec. 5, 2023

(30) Foreign Application Priority Data
Jun. 9, 2020 (AU) 2020901891

(51) Int. Cl. B60L 53/31; B60L 53/16; H02G 3/08; H02G 3/14; H02J 7/00

(52) U.S. Cl. CPC B60L 53/31; B60L 53/16; H02G 3/088; H02G 3/14; H02J 7/0042

(57) ABSTRACT

An apparatus for charging electric vehicles including: a base configured for embedding in the ground: a column configured to extend from the base and retract into the base: a charging interface on or in the column for charging an electric vehicle; and a handle on or in the column configured for manually extending the column.

### TECHNICAL FIELD

The present disclosure relates to apparatuses and methods for charging electric vehicles, e.g., to provide a charging station for electric cars.

### BACKGROUND

Many vehicles, commonly known as electric vehicles, rely partially or entirely on electric power (e.g., electric cars and electric trucks).

Electric vehicles can be charged from various types of charging stations. Public charging stations with high capacity charge rates (and therefore reduced charging times) have been installed for public use in spaces such as shopping centres, and locations typically along major roads or major highways. However, such charging stations can be associated with high installation costs and are likely to be controlled by the electricity companies that install them (who may transfer the high capital costs to users). In addition, public charging stations may not be conveniently located for all electric vehicle users.

Vehicle owners with off-street parking may be able to install a charging station near where they park their vehicle, such as in a garage, carport or driveway. Although such charging stations do not charge as rapidly as the high capacity chargers described above, they provide convenience and can be used to charge an electrical vehicle overnight. However, many individuals do not have access to off-street parking, especially those living in single dwelling housing, and are unable to install a private charging station on their own property. Instead, if such individuals were to use an electric vehicle, they would be likely to park on the street and have to rely on public chargers to recharge their vehicles.

It is desired to address or ameliorate one or more disadvantages or limitations associated with the prior art, or to at least provide a useful alternative.

### SUMMARY

According to the present invention there is provided an apparatus (forming a charging station) for charging electric vehicles including:
a base configured for embedding in the ground;
a column configured to extend from the base and retract into the base;
a charging interface on or in the column for charging an electric vehicle; and a handle on or in the column configured for manually extending the column.

The handle may be on or in an exposed face of the column that is exposed and manually accessible when the column is extended from and retracted into the base.

The handle may be substantially level (flush) with the ground when the column is retracted into the base.

The handle may be a pull fitting for extending the column by pulling. The handle may include a recess. The recess can be provided by a bowl.

The apparatus may include a closed (waterproof) inner housing in the column for housing a connection between the charging interface and an electrical cable.

The apparatus may include a one-way draining valve disposed and configured for draining water from the closed inner housing.

The handle may be integrated with an exposed top plate of the closed inner housing.

According to the present invention there is provided an apparatus (charging station) for charging electric vehicles including:
a base configured for embedding in the ground;
a column configured to extend from the base and retract into the base;
a charging interface on or in the column for charging an electric vehicle;
a closed (and substantially waterproof) inner housing in the column for housing a connection between the charging interface and an electrical cable;
a one-way draining valve for draining water from the closed inner housing; and
a (stainless steel) waterproof cap configured to screw onto a threaded base to ensure the electrical socket when not connected to the charging vehicle is substantially waterproof.

The closed inner housing may include:
a (waterproof) electrical cable gland for sealing an aperture in the closed inner housing for the electrical cable.

The apparatus may include a handle on or in the column for manually extending the column.

According to the present invention there is further provided a method of charging an electric vehicle, including:
extending a column from a base embedded in the ground; and
charging an electric vehicle using a charging interface on or in the column,
wherein the column is manually extended using a handle on or in the column.

The method may include retracting the column into the base.

The method may include locking the column when it is retracted into the base.

Charging the electric vehicle using the charging interface may include connecting a charging plug with a plug stand to the charging interface.

According to the present invention there is further provided a method of charging an electric vehicle, including:
extending a column from a base embedded in the ground;
charging an electric vehicle using a charging interface on or in the column;
housing a connection between the charging interface and an electrical cable; and
draining water from the closed inner housing.

### BRIEF DESCRIPTION OF THE DRAWINGS

Some embodiments of the present invention are hereinafter described, by way of non-limiting example only, with reference to the accompanying drawings, in which:

FIG. 1 is a schematic diagram of a first embodiment of an apparatus for use with an electric vehicle;

FIG. 2 is a diagram of the first embodiment with a charging interface being used with a charging plug:

FIG. 3 is a diagram of the first embodiment with the charging interface sealed by a substantially waterproof cap:

FIG. 4 shows the first embodiment where the column is retracted into the base embedded in the ground:

FIG. 5 is an exploded view diagram of the first embodiment with the column retracted into the base:

FIG. 6 is an exploded view diagram of the first embodiment being used with the charging plug with the column extended from the base:

FIG. 7 is a side view diagram of the first embodiment with the column retracted into the base:

FIG. 8 is a side view diagram of the first embodiment being used with the charging plug with the column extended from the base:

FIG. 9 is a diagram of separated components of the first embodiment:

FIG. 10 is bottom angled-side perspective view of a column and plates that receive the column, and of a housing for a charging socket, in a second embodiment of the apparatus:

FIG. 11 is a bottom view of the column and plates:

FIG. 12 is a bottom side view of the column and plates:

FIG. 13 is a top view of a slide block of the second embodiment:

FIG. 14 is a top view of a top plate of the second embodiment:

FIG. 15 is bottom angled-side perspective view of the column of the second embodiment from a first angle; and

FIG. 16 is bottom angled-side perspective view of the column of the second embodiment from a second angle that is a quarter turn clockwise from the first angle.

### DETAILED DESCRIPTION

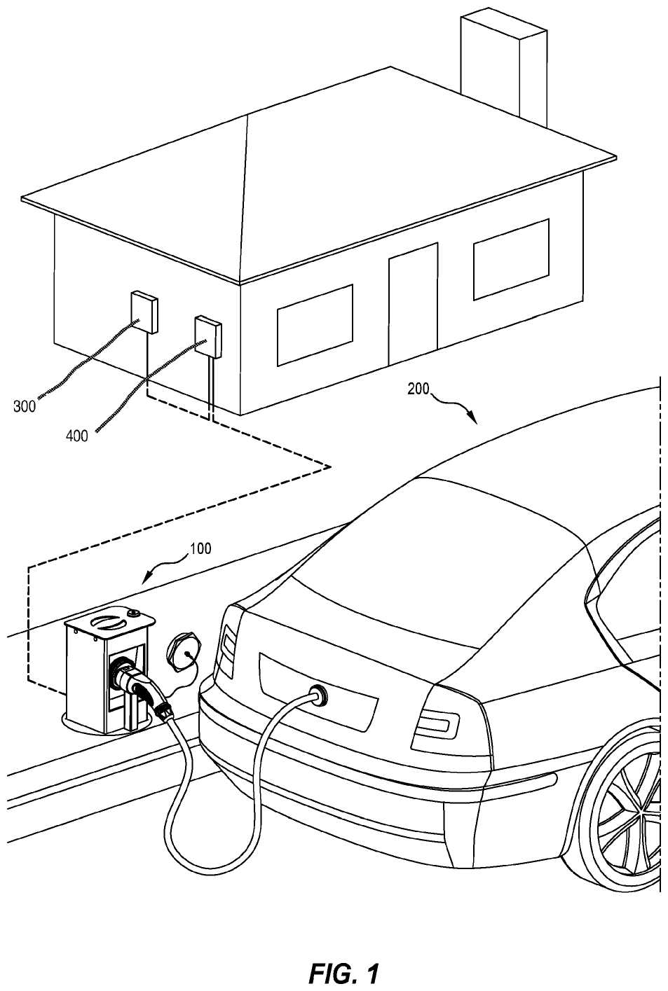

With reference to FIG. 1, described herein is an apparatus 100 for charging an electric vehicle 200. The electric vehicle 200 can be, e.g., an electric car or an electric truck.

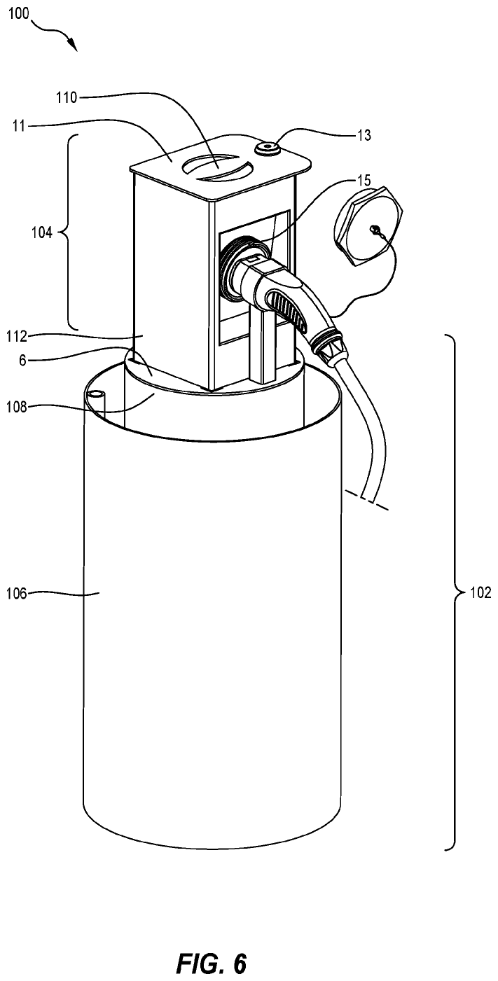

As shown in FIG. 6, the apparatus 100 includes a base 102 configured for embedding in the ground, a column 104 that is configured to and can extend from the base 102 and retract into the base 102, a charging interface 15 on or in the column 104 for charging the electric vehicle 200, and a handle on or in the column 104 configured for manually extending the column 104.

The base 102 may include an outer housing 106 and an intermediate housing 108, or at least the intermediate housing 108.

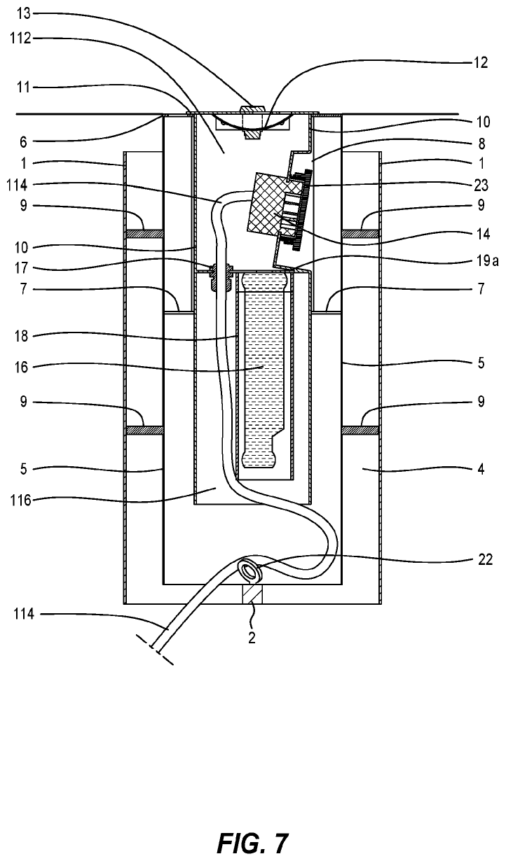

As shown in FIGS. 7, 8 and 9, the outer housing 106 has one or more outer housing walls 1. The outer housing 106 is open at the lower end of the outer housing walls 1, i.e., the end of the outer housing 106 furthest into the ground is not closed (except in some implementations for a tube 2 extending across the centre of the lower end of the outer housing walls 1). A draining pipe can be installed in a trench below the apparatus 100 to assist the spread of any water out of and away from the apparatus 100.

In some implementations, the outer housing 106 may include the tube 2 at the bottom of the outer housing 106 to allow the apparatus 100 to be removed by lifting, e.g., for maintenance or relocation of the apparatus 100. The apparatus may be lifted by attaching a chain or cable, e.g., with a hook, to a pull ring 22 attached to the tube 2. The pull ring 22 can be attached to a substantially middle portion or point of the tube 2, i.e., substantially halfway along its length as show in FIG. 7. The pull ring 22 is sized to receive a hook or chain. The pull ring 22 can be attached to the tube 2 by a weld. The tube 2 extends across a lower end of the outer housing 106 so the outer housing 106 is forced upward when the tube 2 is forced upward (for lifting). The tube 2 is attached to opposed halves of the lower end of the outer housing, e.g., extending through a substantially central point of the lower end so a lifting force applied to a substantially middle point of the tube 2 (i.e., where the pull ring 22 is attached) is divided substantially equally between opposed sides of the apparatus 100: thus pulling upward on the middle of the tube 2 pulls the apparatus substantially upward without providing a substantial torque that would be applied if the lower end of the outer housing 106 were forced upward from a side of the lower end. The tube 2 is attached to the outer housing 106, e.g., by welds. If the apparatus 100 needs to be removed, a chain can be attached to the pull ring 22, and a portable straddle crane can be set up to pull the apparatus 100 out of the ground by pulling on the pull ring 22. The tube 2 can have a square cross section, i.e., it can be a square tube. The cross-sectional width of the tube 2 can be substantially 25 mm, e.g., a 25 mm by 25 mm square cross section.

The intermediate housing 108 has intermediate housing walls 5 as shown in FIGS. 7, 8 and 9. The intermediate housing 108 is disposed inside the outer housing 106, and may be spaced apart from the outer housing 106 by one or more rigid members 9. Each of the rigid members 9 may be fixed to an outer surface of the intermediate housing walls 5. The rigid members 9 extend from the intermediate housing 108 to the outer housing 106 to define a space between the intermediate housing 108 and the outer housing 106: this space is filled by a space-filling medium 4. The opposed rigid members 9 may be in pairs that are substantially longitudinally aligned on opposite sides of the intermediate housing 108, and are substantially equal in a direction from the intermediate housing 108 to the outer housing 106, i.e., generally perpendicular to the surfaces of the intermediate housing 108 and the outer housing 106 that face each other. The rigid members 9 can be substantially equal in their aligned pairs on opposite sides of the intermediate housing 108. The one or more rigid members 9 may assist to centre (i.e., align) the intermediate housing 108 within the outer housing 106. The rigid members 9 may be steel pins attached to the outside of the intermediate housing walls 5 by welds and/or threads.

In some implementations, the rigid members 9 may be threaded bolts that are each fixed to the intermediate housing 108 by a corresponding nut (not shown): each bolt has a bolt head inside the intermediate housing walls 5, a threaded body extending through a correspondingly sized hole in the intermediate housing walls 5, and a nut forcing against the intermediate housing walls 5 on the outside of the intermediate housing walls 5. In some implementations, one or more of the rigid members 9 may be unthreaded bolts welded to the intermediate housing 108.

One or two or more of the upper ones of the rigid members 9 (“supported rigid members”) may be fastened to support plates, e.g., steel plates, inside the intermediate housing 108 to strengthen the connection between these rigid members 9 and the intermediate housing 108, thus allowing these supported rigid members to be used as hoist points to lift the intermediate housing 108, and potentially surrounding concrete, out of the ground for removal thereof, e.g., for uninstalling the apparatus 100.

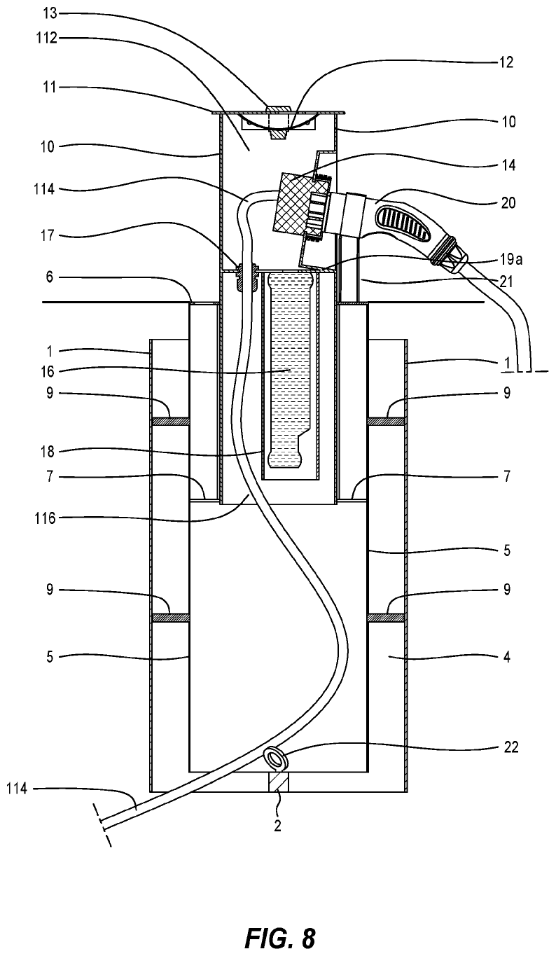

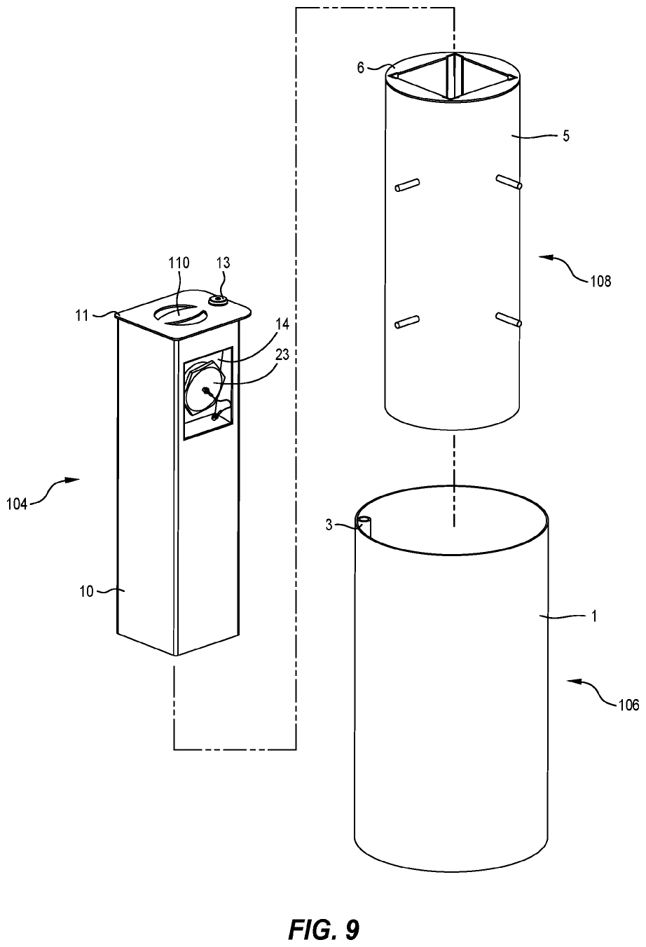

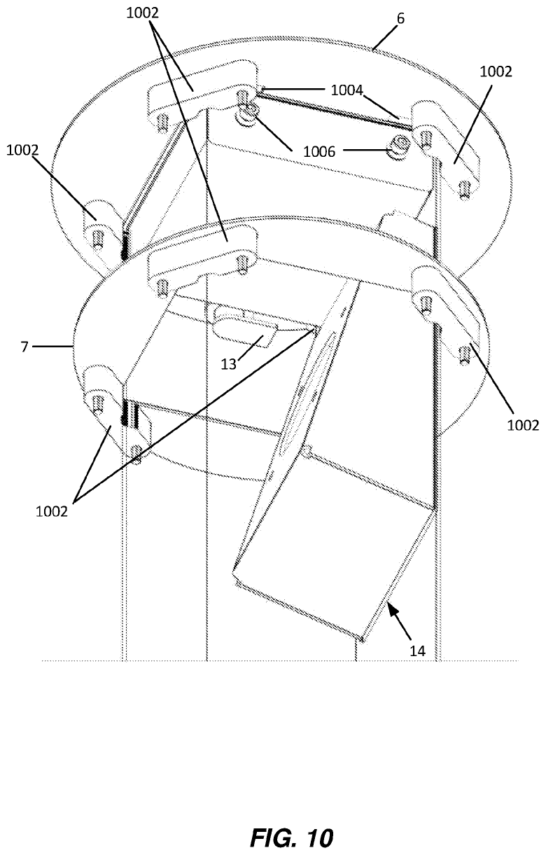

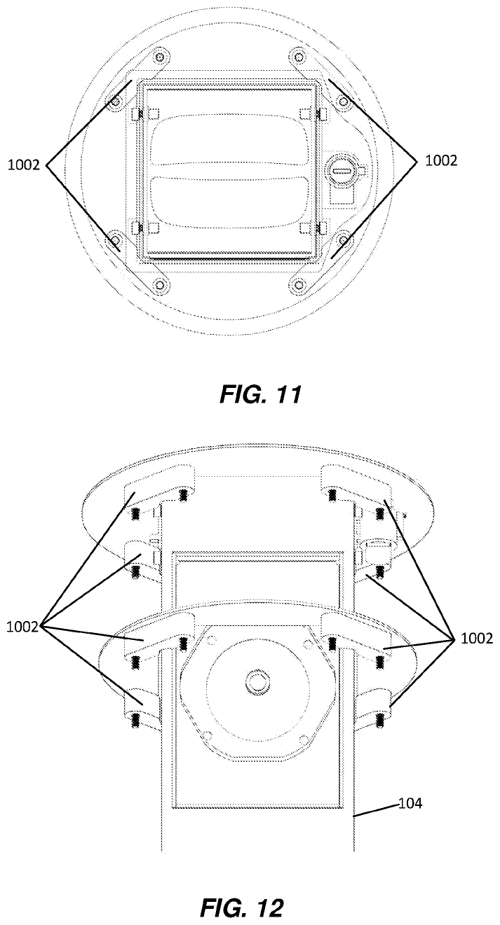

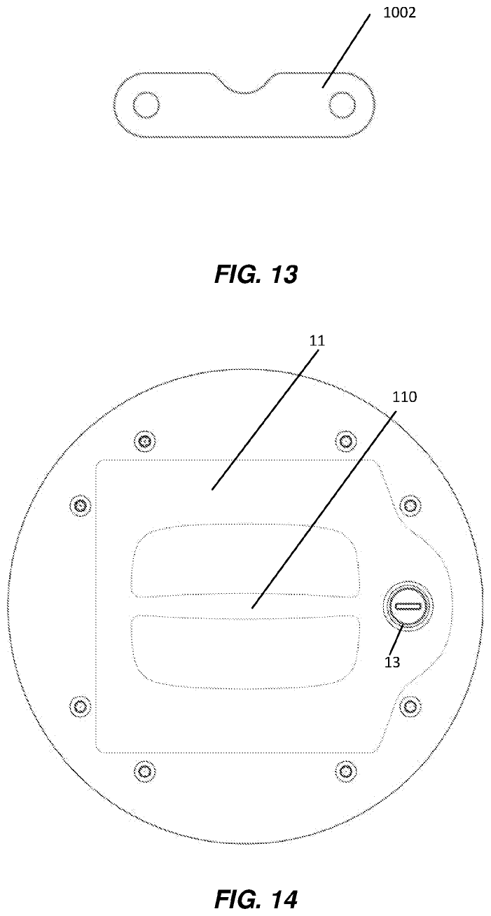

The intermediate housing 108 can include an intermediate top plate 6 at an upper end of the intermediate housing 108 closest to the ground that may be substantially parallel to the ground as shown in FIGS. 9, 10 and 16. The intermediate top plate 6 may be substantially perpendicular to the intermediate housing walls 5 as shown in FIGS. 8, 10 and 16. The intermediate housing 108 can include at least one guiding plate 7 that is substantially perpendicular to the intermediate housing walls 5. The intermediate top plate 6 and the guiding plate 7 are substantially horizontal when installed. The intermediate top plate 6 and the guiding plate 7 each include a cut out for receiving the column 104. The cut out may be of a size such that the column 104 closely fits within the cut out to provide a sliding fit. The sliding fit may be provided by a plurality of slide blocks 1002 formed of a low-friction material, e.g., a low-friction polymer, e.g., polyoxymethylene (POM) or acetal, e.g., in the form of Delrin™ from Dupont, as shown in FIGS. 10-13. The slide blocks 1002 may be arranged and held around each cut out, as shown in FIGS. 10-12, so that the slide blocks 1002 push against the sides of the column 104, including as it moves up and down through the cut out, and therefore the column 104 bears against the slide blocks 1002, rather than directly against the intermediate top plate 6 and the guiding plate 7, when in use. As shown in FIGS. 10-12, the slide blocks 1002 may be mounted at the corners of the cut outs, thus bearing against the corresponding corners of the column 104. As shown in FIGS. 10-12, the slide blocks 1002 may be mounted to the corners using a secure mechanical fastening, e.g., nuts and bolts. This may improve the extension and retraction of the column 104 from the base 102. The intermediate housing 108 is open at the bottom end of the intermediate housing walls 5, i.e., the end of the intermediate housing 108 furthest into the ground, i.e., opposite the intermediate top plate 6 at the upper end, to allow water than condenses in and/or enters the column 104, e.g., due to condensation and/or rain, to flow down out of the column 104 to the open lower end of the outer housing 106.

The apparatus 100 includes a conduit 3 fixed by brackets to the inner surface of the outer housing walls 1 as shown in FIGS. 5 and 9. The conduit 3 extends down, from the upper end of the outer housing 106, towards the lower end of the outer housing 106, at least to below the lower end of the movable column 104 when the column 104 is at its lowest position in the base 102: i.e., when an exposed top plate 11 of the column 104 rests due to the force of gravity against the intermediate top plate 6, resisting further downward movement of the column 104. From its lowest point, the conduit bends upward to face towards the lower end of the column 104. The apparatus 100 can include a restraining cable that is anchored at one end to an upper mouth of the conduit 3 (i.e., at the upper end of the base 102), e.g., by a manually removable anchor fixed to the cable and larger than the diameter of the conduit 3. The restraining cable is attached at its other end to the column 104, and a length of the cable is selected to limit the rise of the column 104 out of the base 102 to be sufficient to expose a charging interface 15, but to keep the column 104 at least partially in the base 102: e.g., at least 10%, 25%, 40% or 50% in the base 102, e.g., as shown in FIG. 8. The anchor can be removed manually to allow complete release of the column 104 from the base 102, e.g., for maintenance. The restraining cable and the anchor form a tether configured to limit upward extension of the column 104 from the base 102 when in use.

The outer housing 106 is larger than the intermediate housing 108 so the intermediate housing 108 fits within the outer housing 106. In the vertical direction, when installed, the longitudinal (vertical) length of the outer housing 106 is larger than the longitudinal (vertical) length of the intermediate housing 108. In the horizontal direction, when installed, an average diameter of the outer housing 106 is larger than an average diameter of the intermediate housing 108. In some embodiments, the outer housing walls 1 of the outer housing 106 can be a cylinder with a diameter between 300 and 500 mm and a height between 500 and 700 mm. The intermediate housing walls 5 can be a cylinder with a diameter between 200 and 300 mm and a height between 500 and 700 mm (e.g., depending on the dimensions of the outer housing walls 1).

The intermediate top plate 6 is fixed to the upper end of the intermediate housing 108, abutting and covering the upper edges of the intermediate housing walls 5. The intermediate housing walls 5 support the intermediate top plate 6 against the force of gravity, including when the column 104 rests on the intermediate top plate 6.

The guiding plate 7 is fixed to the inner surface of the intermediate housing walls 5. The guiding plate 7 can be a circle with a diameter to fit in the cylinder (e.g., slightly smaller than the diameter of the cylinder of the intermediate housing walls 5). The cut out for receiving the column 104 may be a rectangular cut out with a perpendicular lengths of between 100 mm and 200 mm each, e.g., a square cut out of substantially equal perpendicular lengths, e.g., equal to substantially equal to 150 mm by 150 mm or 120 mm by 120 mm, or a rectangle or square with sides each between 100 mm and 200 mm.

The outer housing 106 and the intermediate housing 108 can be separated by the space-filling medium 4, e.g., concrete. The one or more rigid members 9 may assist to anchor the intermediate housing 108 to the medium 4.

In some implementations, the outer housing 106 and the intermediate housing 108 may include stainless steel components, e.g., any or all of the outer housing walls 1, the tube 2, the intermediate housing walls 5, the top plate 6, and the guiding plate 7 may be stainless steel. In some implementations, the outer housing 106 may include plastic polymer components, e.g., the outer housing walls 1 may include plastic polymer walls, e.g., polyvinyl chloride (PVC)—the outer housing walls 1 may be a PVC pipe section. The outer housing 106 need not always be as strong/resilient as the intermediate housing 108 and the column 104 because the outer housing 106 may merely be formwork, defining a space for the space-filling medium 4 such as concrete.

The column 104 can extend from the base 102 and retract into the base 102. FIGS. 7 and 8 respectively show the column 104 retracted into the base 102 and extended from the base 102. The column 104 may be extended from the base 102 for charging the electric vehicle 200, and retracted into the base 102 when the electric vehicle 200 is not charging, i.e., the column 104 is stored in the base 102 when the apparatus 100 is not required for charging the electric vehicle 200.

In some implementations, the base may include one or more rails 8 for guiding the extension and retraction of the column 104. The rails 8 can be stainless steel. The rails 8 are substantially vertical when installed. In some implementations, the rails 8 are not required because the slide blocks 1002 orient and guide the column 104 during extension and retraction as described hereinbefore.

The charging interface 15 is provided on or in the column 104. The charging interface 15 includes electrical conductors for charging the electric vehicle 200 via a charging plug 20 from the electric vehicle 200 plugged into the charging interface 15. The charging interface 15 may be, for example, a female charging socket, e.g., a Mennekes™ Type 2 female charging socket. The charging interface 15 is connected to a cable 114. The cable supplies electric current to the apparatus 100 so that the apparatus 100 can be used to charge the electric vehicle 200.

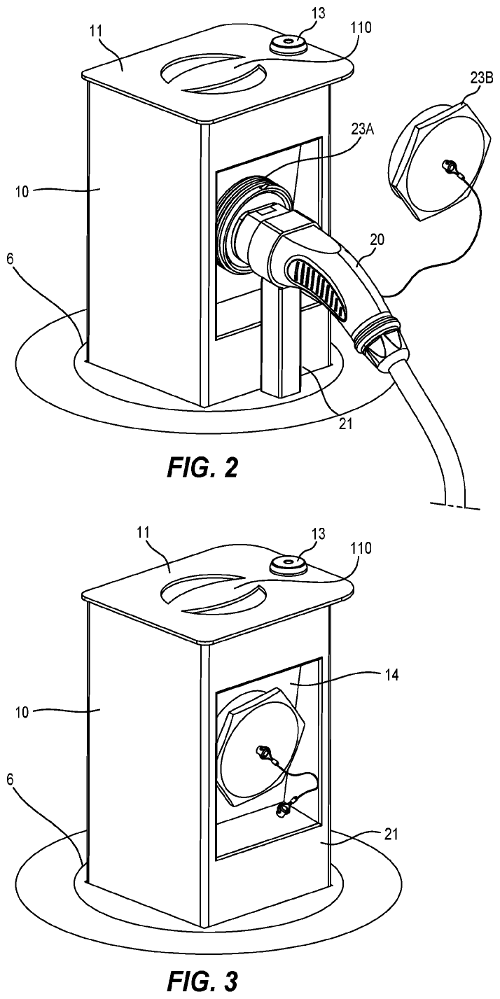

The charging interface 15 includes a waterproof cover 23 that covers the electrical conductors to protect them from external water, e.g., as shown in FIGS. 7 and 8, e.g., with an Ingress Protection (IP) code/rating of at least 54, 67 or 68 according to the IEC standard 60529. The waterproof cover 23 is configured to be opened under manual force to expose the electrical conductors for the charging plug 20 to connect to the charging interface 15 electrically. The waterproof cover 23 can include a base 23A (“threaded base”) with male threads welded to a housing 14 (“plug housing”), as shown in FIG. 2, and a stainless steel female threaded waterproof cap 23B, as shown in FIG. 3, with an O-ring manually screwed and unscrewed to the male base of the waterproof cover 23 to respectively cover or expose the charging interface 15. Alternatively, the waterproof cover 23 can pivot on a hinge above the electrical conductors, when installed.

### Handle

As shown in FIG. 2, the apparatus 100 includes a handle 110 on or in the column 104 for manually extending the column 104 from the base 102. The handle 110 can be used by a user to manually extend or raise the column 104 from the base 102, so that the charging interface 15 can be accessed for charging the electric vehicle 200. The handle 110 can be used by a user to manually lower the column 104 into the base 102 in a controlled manner. Alternatively, the column 104 can be allowed to drop into the base 102 under the force of gravity.

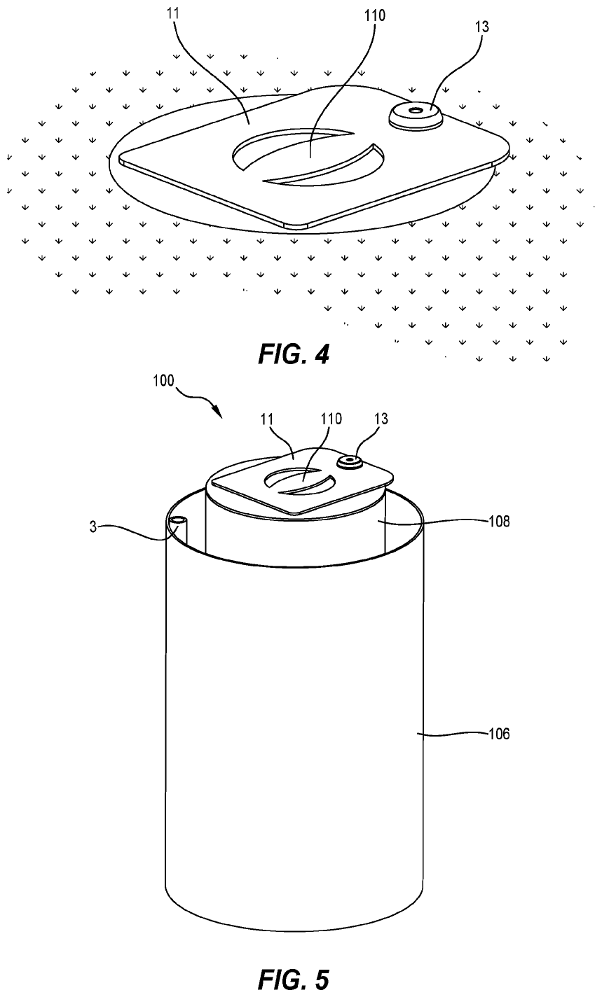

As shown in FIGS. 3 and 4, the handle 110 may be on or in an exposed face of the column 104 that is exposed and manually accessible when the column 104 is retracted into the base 102.

The handle 110 may be substantially level (flush) with the ground when the column 104 is retracted into the base 102, i.e., when the column 104 is not extended from the base 102, the handle 110 does not substantially protrude from the ground. This may improve the safety of the user and others, who are less likely to trip over or injure themselves on the apparatus 100 while the column 104 is retracted in the base 102.

The handle 110 may be a pull fitting for extending the column 104 by pulling, i.e., when the user pulls on the pull fitting, the column 104 extends from the base 102. The handle 110 may include a recess in and under the exposed top plate 11. The recess can include one or more cut outs (or apertures), which are generally semicircular, in a top face of the exposed top plate 11, such that the top of the recess is substantially continuous with the exposed top plate 11.

The handle 110 may be located at an upper end of the column 104, such that the upper end of the column 104 is furthest from the base 102 when the column 104 is extended from the base 102.

The handle 110 may be at least partially stainless steel. The recess can be provided by a bowl 12 (e.g., a stainless steel bowl) that can be attached to the exposed top plate 11, e.g., by a weld between an open upper lip of the bowl 12 and an underside surface of the exposed top plate 11. The weld can be continuous to form a water-resistant or waterproof seal between the bowl 12 and the exposed top plate 11. Thus, the bowl 12 and its weld can keep the exposed top plate 11 and the recess substantially waterproof, e.g., to an IP code/rating of at least 54, 67 or 68, and keep the closed inner housing 112 substantially closed and dry. Water may collect in the bowl 12 when installed, but the bowl 12 is shaped and located to gather the water away from the weld (between the bowl 12 and the exposed top plate 11), and the weld is water-resistant or waterproof, thus the closed inner housing 112 resists penetration of this collected water which will tend to evaporate because the recess is exposed. The bowl 12 is sized to receive an adult human hand, or at least adult fingers to pull on the handle to pull up the column 104, thus the recess is sized to receive an adult human hand, or at least adult fingers to pull on the handle to pull up the column 104. The recess can extend under the underside of the exposed top plate 11, beyond the one or more cut outs, such that a portion (a “grip portion”) of the exposed top plate 11 extends above the recess, and this portion can be gripped by the hand reaching through one of the cut outs, i.e., manually, thus this grip portion forms a pull fitting for extending the column 104 by pulling, i.e., when the user pulls on the portion, the column 104 extends from the base 102, that is equivalent in function to the handle 110—the handle 110 may include this grip portion. The welded upper lip of the bowl 12 can be located a substantial distance from the outer edge or edges of the one or more cut outs (in the top plate 11) to create one or more grip portions around the recess under the handle 110. Thus the one or more cut outs can define one or more areas (or openings) that are substantially smaller than an area defined by the boundary or opening of the bowl 12. The upper lip of the bowl 12 defines the boundary or opening of the bowl 12. The opening of the bowl can be substantially circular or substantially rectangular, including substantially square, when viewed from the top. The cut outs can be substantially semicircular or substantially rectangular or substantially elliptic or generally oval-shaped, as shown in FIG. 14, and positioned over the opening of the bowl 12. The size of the bowl 12 may be: approximately 50 mm to 200 mm in diameter, e.g., substantially 100 mm or 65 mm diameter, i.e., substantially circular; or approximately 110 mm in length and approximately 80 mm in width, i.e., substantially rectangular: or approximately 90 mm in length and 90 mm in width, i.e., substantially square. The bowl 12 may be approximately 40 mm deep. As shown in FIG. 14, the handle 110 can be accessed from both sides because there are two cut outs in the exposed top plate 11, thus the handle 110 can be easily access by a person's left hand and right hand equally.

For the threaded cap 23B, the charging plug 20 can be inserted into the charging interface 15 by the manual action of the user extending the column 104 with one hand, unscrewing the female threaded cap 23B of the waterproof cover 23 with the other hand, then releasing the female threaded cap 23B and using the same hand to insert the charging plug 20 into the charging interface 15.

For a hinged version of the cap, having the bowl 12 placed close to the charging interface 15 in the recess of tube 104, e.g., substantially above the charging interface 15, enables a person to hold open the waterproof cover 23 of the charging interface, while lifting the column 104, with one hand. That is, the handle, and thus the bowl 12, can be located substantially above the charging interface 15 (when installed) such that the handle and the waterproof cover 23 (of the charging interface 15) can be held by one hand (a first hand), e.g., with fingers holding the handle (to hold the column 104 up) and a thumb of the same hand holding the waterproof cover 23 open. The charging plug 20 can then be inserted into the charging interface 15 (since the waterproof cover 23 is open, held by the first hand) by the other hand (a second hand) of the person.

Where the recess under the handle 110 includes more than one cut out, the cut outs may be positioned over the opening of the bowl 12 such that a portion of the top plate 11 can form the pull fitting, i.e., by forming a member (marked as the handle 110 in FIGS. 2 to 5) that may be used as a grip, e.g., by a user manually gripping the member (by reaching through one or more of the cut outs) to use the handle 110. For example, the recess may include two cut outs that are arranged such that the top plate 11 forms the member (e.g., a bar) between the two cut outs. The two cut outs can be substantially semicircular, and arranged such that the baselines of each of the cut outs are closest together and are separated by the member or bar, and the arcs of each of the cut outs are furthest away from each other. The two cut outs can fit within a rectangle substantially 90 mm by 75 mm. The member or bar can be substantially 15 mm wide and substantially 75 mm or 90 mm long, i.e., bridging over the cut outs.

### Closed Inner Housing

The column may include a closed inner housing 112. The closed inner housing 112 houses a connection between the charging interface 15 and the cable 114.

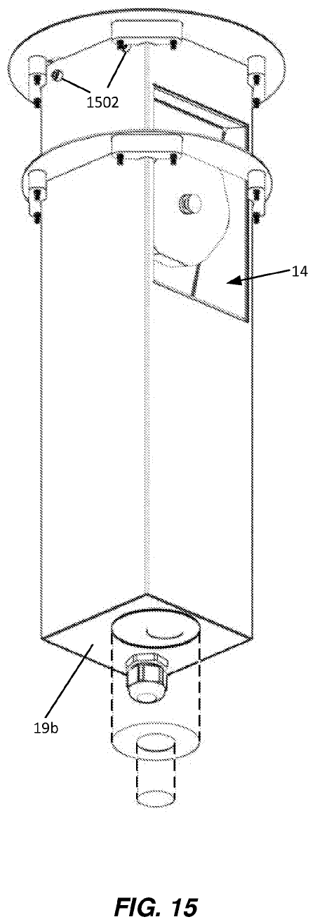

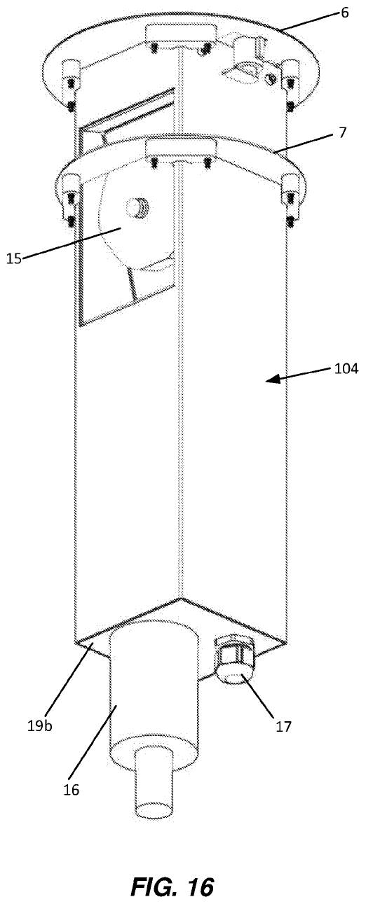

The closed inner housing 112 may include a tube 10, extending vertically when installed, the exposed top plate 11 and an intermediate surface 19a (as shown in FIG. 7) or a bottom surface 19b (as shown in FIG. 15). The bottom surface 19b (as shown in FIG. 15) may be easier to weld to the tube 10 than the intermediate surface 19a (as shown in FIG. 7), although implementations with the bottom surface 19b have a one-way draining valve 16 extending further into the ground when installed (as shown in FIG. 16) compared to implementations with the intermediate surface 19a (as shown in FIG. 7). The exposed top plate 11 and the intermediate surface 19a or the bottom surface 19b extend horizontally when installed. The exposed top plate 11 and the intermediate surface 19a or the bottom surface 19b enclose the tube 10 so that the closed inner housing 112 is closed and sealed. This may prevent or minimise water ingress into the closed inner housing 112, keeping the closed inner housing 112 substantially waterproof. The intermediate surface 19a or the bottom surface 19b may be the shape of a cross-section of the tube 10 and be fitted in or on the tube 10 such that it seals one end of the closed inner housing 112, e.g., the intermediate surface 19a or the bottom surface 19b may be fused (e.g., welded) with the tube 10. The exposed top plate 11 may have a shape of a cross-section of the tube 10, or may have a shape larger than a cross-section of the tube 10, e.g., so that the exposed top plate 11 laterally projects from the tube 10. The exposed top plate 11 may be a strong weatherproof top, which is substantially waterproof, e.g., to an IP code/rating of at least 54, 67 or 68, for the closed inner housing 112. The exposed top plate 11 can include an oblong shape or a circular shape, or a substantially square shape, for example, with straight sides and curved or rounded corners, e.g., as shown in FIG. 14. The four curved corners may have mutually different corner radii. Two of the corners may have a larger corner radius than the other two corners, e.g., two corners joined by an edge of the exposed top plate 11 may have a larger corner radius than the other two corners. Where the apparatus 100 includes a manual lock (e.g., as described below), and the lock is provided on the exposed top plate 11, the edge joining the two corners with the larger corner radius may be the edge of the exposed top plate 11 closest to the lock.

The exposed top plate 11 of the closed inner housing 112 can be at the upper end of the column 104.

The exposed top plate 11 can be removably attached to the tube 10 so that the exposed top plate 11 is removable for installation and maintenance of the apparatus 100, e.g., maintenance of the charging interface 15 or maintenance of the cable 114. The exposed top plate 11 may be attached to the tube 10 by bolts 1006, as shown in FIG. 10. The exposed top plate 11 can be fastened to the tube 10, e.g., by the bolts, to form a water-resistant or waterproof seal between the exposed top plate 11 and the tube 10, e.g., to an IP code/rating of at least 54, 67 or 68. A plurality of the bolts 1006 (e.g., three or four bolts, arranged substantially horizontally when installed) can be installed in the sides of the tube 10, underneath the exposed top plate 11. These bolts 1006 can be fixed in place by holes 1502 that extend through the tube 10, as shown in FIG. 15, into vertical stainless steel pieces (i.e., vertical when in use) welded to top plate 11 that form the bowl 12. These holes 1502 can be threaded, or can have rivet nuts installed (also referred to as “riv nuts” or “nut serts)”, to provide a thread in each hole 1502 to fasten the bolts 1006 in place. These holes 1502 can be drilled with a countersunk drill such that the bolt heads of bolts 1006 do not protrude to inhibit the smooth extension/retraction of the column 104, or the bolt heads 1006 can project and pass through notches 1004, which are in the cut out in the intermediate top plate 6 as shown in FIG. 10, which allow vertical passage of the bolt heads 1006 projecting from the sides of the column 104. These bolts 1006 can be installed with a waterproof sealant and/or adhesive (e.g., including a thread locker such as Loctite™) to improve waterproof integrity of the closed inner housing 112. These bolts 1006 may be short, e.g., around 8 mm-20 mm.

Alternatively, instead of bolts 1006, the exposed top plate 11 may be permanently attached to the tube 10, including by sealing welds around the top edge of the tube 10 (i.e., continuously around the edge of the tube 10 touching the exposed top plate 11).

The handle 110 may be integrated with the exposed top plate 11 of the closed inner housing 112. Where the handle 110 includes the recess, the recess may be defined by the bowl 12 attached to the exposed top plate 11.

The charging interface 15 may be in or on the closed inner housing 112, such as in or on the tube 10. For example, the charging interface 15 and the waterproof cover 23 may be in or on a recess of the tube 10 to allow better extension and retraction of the column 104, i.e., so that the charging interface 15 and waterproof cover 23 do not interfere with the extension and/or retraction of the column 104 through the cut out in the intermediate top plate 6. The charging interface 15 and the waterproof cover 23 may be housed in the “plug” housing 14, which forms a box. The “plug” housing 14 can be partially disposed inside the closed inner housing 112, i.e., as a cavity in the closed inner housing 112. As shown in FIGS. 7 and 8, the “plug” housing 14 and the waterproof cover 23 may be set (mounted) at a downward facing angle between 15 and 30 degrees (down from horizontal) to guide any water to flow away from the charging interface 15 by gravity, i.e., so surfaces in the “plug” housing 14 and the waterproof cover 23 are oriented to direct water flow away from the closed inner housing 112.

The exposed top plate 11 may be above the charging interface 15, while the intermediate surface 19 or the bottom surface 19b is below the charging interface 15, so that the charging interface 15 is between the exposed top plate 11 and the intermediate surface 19 or the bottom surface 19b.

By housing the connection between the charging interface 15 and the cable 114, the closed inner housing 112 may protect the connection from damage such as water damage.

The charging interface 15 may be sealed by a waterproof potting compound, e.g., the charging interface 15 may be sealed on an inner surface of the closed inner housing 112 by the waterproof potting compound, e.g., to an IP code/rating of at least 54, 67 or 68. This may prevent water ingress at or around the charging interface 15 and the connection between the charging interface 15 and the cable 114.

In some embodiments, the tube 10 can have a rectangular or square cross section with a side length between 100 and 180 mm, e.g., substantially 150 mm or 120 mm, wherein each cross-sectional dimension (i.e., horizontal dimension when in use) of the tube 10 is less than the corresponding cross-sectional dimension of the cut out for receiving the column 104 so the tube 10 has a sliding fit (or “slip fit”) or a loose running fit in the cut out so the tube 10 can slidingly fit into the intermediate housing 108, e.g., between 0.01 mm and 1.0 mm less in each cross-sectional dimension than the cut out, e.g., substantially 0.4 mm smaller, leaving gaps of substantially 0.2 mm on average between the tube 10 and the cut out on each side. The sliding fit may be provided by the slide blocks 1002 as described hereinbefore. The intermediate surface 19a or the bottom surface 19b may be a square with a side length slightly smaller than the side length of the cross section of the tube, so that the intermediate surface 19a or the bottom surface 19b fits closely in the square tube such that the closed inner housing 112 is sealed and thereby water ingress into the closed inner housing 112 may be minimised.

In certain embodiments, the closed inner housing 112 may include stainless steel components, i.e., any or all of the tube 10, the exposed top plate 11, the intermediate surface 19a or the bottom surface 19b, and the housing 14 may be stainless steel, joined by welds. The welds joining these stainless steel components can be continuous welds to form respective water-resistant seals or waterproof between the components: e.g., between the tube 10 and the intermediate surface 19a or the bottom surface 19b; and/or between the tube 10 and the “plug” housing 14, e.g., to an IP code/rating of at least 54, 67 or 68.

### One-Way Draining Valve

The apparatus 100 may include the one-way draining valve 16 disposed and configured for draining any water from the closed inner housing 112. The one-way draining valve 16 removes water such as condensate from the closed inner housing 112 via a saturated one-way membrane. A standard one-way valve may not be effective due to a lack of head pressure. The water is collected by the valve 16, and is removed from the valve 16 by falling to the lower end of the intermediate housing 108 due to gravity, and from there seeps into the ground around the apparatus 100.

The one-way draining valve 16 is fixed to the closed inner housing 112 and may be connected to the closed inner housing 112 by a fitting such as a threaded male pipe installed in the intermediate surface 19a or the bottom surface 19b. For example, the one-way draining valve 16 can be fixed to an outer side of the intermediate surface 19a or the bottom surface 19b that is not inside the closed inner housing 112.

In some implementations, the apparatus 100 may include a valve housing 18 to protect the one-way draining valve 16. The valve housing 18 may be affixed to the closed inner housing 112, such as to the outer side of the intermediate surface 19a or the bottom surface 19b. The valve housing 18 can be a cylinder. In some embodiments, the valve housing is a cylinder with a diameter of 80 mm and a height of 250 mm. The valve housing 18 may also provide a wrapping guide for the cable 114, which may improve cable management. In some implementations, the valve housing 18 can be a stainless steel cylinder.

The one-way draining valve 16 can be a one-way, dry-sealing and self-sealing low-pressure plumbing valve in a water pipe, e.g., a HepvO or HepvO™ valve in a PVC pipe, that opens under the water pressure of the condensation collecting, and closes to form an air-tight seal after the condensation has discharged under normal atmospheric pressure.

### Electrical Cable Gland

As shown in FIGS. 7, 8 and 16, the closed inner housing 112 may include an electrical cable gland 17 for sealing an aperture in the closed inner housing 112 for the cable 114. The electrical cable gland 17 is a waterproof electrical cable gland and may improve the waterproof integrity of the closed inner housing 112 by preventing water ingress through the aperture, e.g., to an IP code/rating of at least 54, 67 or 68. The aperture allows the cable 114 to pass into the closed inner housing 112. The aperture may be in the intermediate surface 19a or the bottom surface 19b.

### Open Inner Housing

As shown in FIGS. 7 and 8, in some implementations the column 104 may include an open inner housing 116. The open inner housing 116 is connected to the closed inner housing 112. The open inner housing 116 may be continuous with the closed inner housing 112, i.e., the open inner housing 116 can include a tube that is continuous with the tube 10 of the closed inner housing 112. The open inner housing 116 and the closed inner housing 112 can be separated by the intermediate surface 19a. The open inner housing 116 may house the one-way draining valve 16. The open inner housing 116 may house a portion of the cable 114 extending from the closed inner housing 112. The portion of the cable 114 may extend from the closed inner housing 112 to the open inner housing 116 via the aperture and the electrical cable gland 17. In certain embodiments the open inner housing 116 can be stainless steel.

Alternatively, as shown in FIGS. 15 and 16, the entire column 104 may be the closed inner housing 112 terminated by the bottom surface 19b, i.e., the apparatus 100 need not include the open inner housing 116.

### Lock

The apparatus 100 may include a manual lock 13 for locking the apparatus 100 when the column 104 is retracted into the base 102. The lock 13 may prevent an unauthorised user from extending the column 104 and accessing the charging interface 15. The lock 13 can be manually unlocked so that the column 104 can be manually extended from the base 102 using the handle, and the charging interface 15 can be accessed to charge the electric vehicle 200. When the column 104 retracts into the base 102, the lock 13 may be engaged to lock the apparatus 100. The lock 13 is provided on the apparatus 100 so that the lock 13 is accessible to be unlocked when the column 104 is retracted into the base 102. The lock 13 may, for example, be provided on the exposed top plate 11 of the closed inner housing 112. The lock 13 can be located on a portion of the exposed top plate 11 that laterally projects from the tube 10. The lock 13 may lock the column 104 to the base 102, e.g., by locking the exposed top plate 11 to the top plate 6 of the intermediate housing 108.

In certain embodiments, the lock 13 can be a stainless steel lock.

### Charging Plug and Plug Stand

As shown in FIG. 2, the apparatus 100 is used to charge the electric vehicle 200 using a charging plug 20. The charging plug 20 is connected to the charging interface 15 to allow electricity to flow to and charge the electric vehicle 200. The charging plug 20 may be a male charging plug, i.e., to be used with a female charging interface, such as a Mennekes™ Type 2 male plug.

The charging plug 20 may have a plug stand 21. The plug stand 21 prevents the charging plug 20 from resting on the ground when the charging plug 20 is connected to the charging interface 15. The column 104 may be maintained in a completely or partially extended position (i.e., completely or partially extended from the base 102) by the charging plug 20 with the plug stand 21 being connected to the charging interface 15. When the charging plug 20 (and plug stand 21) are removed from the charging interface 15, i.e., disconnected from the charging interface 15, the column 104 may be free to retract into the base 102, e.g., via the force of gravity and/or by being pushed.

The plug stand 21 may be attached to the charging plug 20, e.g., by a hose clamp. In certain embodiments, the plug stand 21 can be stainless steel.

The length of the restraining cable is selected to allow the charging interface 15 to be raised sufficiently above the intermediate top plate 6 to accommodate the plug stand 21 as shown in FIG. 8.

The handle can be used by a user to manually raise the column 104 to release the plug stand 21 and thus the charging plug 20.

### Counterweight/Spring

To improve manual operation of the apparatus 100, it may include one or more counterweight and/or spring systems to reduce the weight of the column 104. The counterweight system may include a saddle or attachment point substantially at the bottom of the column 104, and a pulley or low-friction saddle beneath the guiding plate 7 and inside the intermediate housing 108. The pulley or low-friction saddle may be fastened to the underside of the guiding place 7, or may be fastened to an inner face of the intermediate housing walls 5. The counterweight system may include counterweights (e.g., steel rods, each approximately 1 kg) hanging from a cable from the attachment point via the low-friction saddle or pulley. In an example, two 1-kg counterweights can reduce the lift weight of the column 104 to approximately 3 kg. The spring system may include one or more springs reducing the weight of the column 104 in compression or in extension, e.g., mounted between the lower side of the guiding plate 7 and the bottom of the column 104, e.g., a single spring coiled around the column 104.

### Electrical Connection and Installation

As shown in FIG. 1, the apparatus 100 may be connected to an isolated electrical circuit that is connected to a switchboard such as a residential switchboard 300 as shown in FIG. 1. In this respect, the cable 114 of the apparatus 100 may be connected to the circuit. The circuit may be referred to as a wall-based charging station 400. The wall-based charging station 400 can include a relay switch that prevents current from flowing through the circuit unless the vehicle 200 is being charged using the apparatus 100. This may improve safety and optimise electricity usage. The relay switch may be configured to receive an electric signal representing that the vehicle 200 is correctly connected to the apparatus 100, where upon receipt of the electric signal the relay switch allows current to flow through the circuit to the apparatus 100. The wall-based charging station can include a dial such as a manual dial for adjusting the current, or a dynamic charging switch that automatically adjusts the current, for the circuit based on power available from the switchboard 300. The wall-based charging station may be installed above ground level, e.g., on an external wall of a building. The relay switch may also be referred to as a “safety switch”.

A conduit carrying an electric cable from the relay switch to the apparatus 100 may be installed in a trench. The trench may be created, for example, by vacuum excavation and/or conventional digging.

The outer housing 106 is installed vertically in a trench or vertical hole adjacent a kerb or parking space for the electrical vehicle. The outer housing 106 may be secured in the ground by concrete.

The current received by the electric vehicle 200 from the apparatus 100 may be AC current. In certain embodiments, the electric vehicle 200 can transform the current received from the apparatus 100 to DC current to charge a battery of the electric vehicle 200.

### Method

Described herein is a method of charging the electric vehicle 200, including:
extending the column 104 from the base 102 embedded in the ground;
charging the electric vehicle 200 using the charging interface 15 on or in the column 104;
wherein the column 104 is manually extended using the handle on or in the column 104.

The method may include:
retracting the column 104 into the base 102; and/or
locking the column 104 when it is retracted into the base 102.

Charging the electric vehicle 200 using the charging interface 15 may include connecting the charging plug 20 with the plug stand 21 to the charging interface.

The method may include:
extending the column 104 from the base 102 embedded in the ground;
charging the electric vehicle 200 using the charging interface 15 on or in the column 104;
housing the connection between the charging interface 15 and the electrical cable 114; and
draining water from the closed inner housing 112.

The method may include installing the base 102 and the column 104 by:
digging a trench in the ground (by vacuum excavation);
securing the base 102 in the ground;
installing a conduit in the trench carrying an electric cable from a relay switch to the base 102;
installing the column 104 in the base 102;
connecting the charging interface 15 to the electrical cable 114; and
restraining the column 104 in the base 102 using a restraining cable.

### Interpretation

Many modifications will be apparent to those skilled in the art without departing from the scope of the present invention.

The recitation of a particular numerical value or value range herein is understood to include or be a recitation of an approximate numerical value or value range, for instance, within +/−20%, +/−15%, +/−10%, +/−5%, +/−2.5%, +/−2%, +/−1%, +/−0.5%, or +/−0%. Where the context allows, the term “substantially” can indicate a percentage greater than or equal to 80%, 85% or 90%, for instance, 92.5%, 95%, 97.5%, 99%, or 100%.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

1. An apparatus for charging electric vehicles including:
a base configured for embedding in the ground;
a column configured to extend from the base and retract into the base;
a charging interface on or in the column for charging an electric vehicle; and
a handle on or in the column configured for manually extending the column.

2. The apparatus of claim 1 wherein the handle is on or in an exposed face of the column that is exposed and manually accessible when the column is extended from and retracted into the base.

3. The apparatus of claim 1 wherein the handle is substantially level with the ground when the column is retracted into the base.

4. The apparatus of claim 1 wherein the handle includes:
a pull fitting for extending the column by pulling; and/or
a recess, wherein the recess is provided by a bowl.

5. The apparatus of claim 1 wherein the apparatus includes a waterproof closed inner housing in the column for housing a connection between the charging interface and an electrical cable.

6. The apparatus of claim 5 wherein the apparatus includes a one-way draining valve disposed and configured for draining water from the closed inner housing.

7. The apparatus of claim 5 wherein the handle is integrated with an exposed top plate of the closed inner housing.

8. An apparatus for charging electric vehicles including:
a base configured for embedding in the ground;
a column configured to extend from the base and retract into the base;
a charging interface on or in the column for charging an electric vehicle;
a closed and substantially waterproof inner housing in the column for housing a connection between the charging interface and an electrical cable;
a one-way draining valve for draining water from the closed inner housing; and
a waterproof cap configured to screw onto a threaded base to ensure the electrical socket when not connected to the charging vehicle is substantially waterproof.

9. The apparatus of claim 8, wherein the apparatus includes a handle on or in the column for manually extending the column.

10. The apparatus of claim 1 wherein the closed inner housing includes a waterproof electrical cable gland for sealing an aperture in the closed inner housing for the electrical cable.

11. A method of charging an electric vehicle, including:
extending a column from a base embedded in the ground; and
charging an electric vehicle using a charging interface on or in the column, wherein the column is manually extended using a handle on or in the column.

12. The method of claim 11 including retracting the column into the base.

13. The method of claim 11 including locking the column when it is retracted into the base.

14. The method of claim 11 wherein the charging of the electric vehicle using the charging interface includes: connecting a charging plug with a plug stand to the charging interface.

15. A method of charging an electric vehicle, including:
extending a column from a base embedded in the ground;
charging an electric vehicle using a charging interface on or in the column;
housing a connection between the charging interface and an electrical cable; and
draining water from the closed inner housing.
